(19) United States
(12) Patent Application Publication
(10) Pub. No.: US 2026/0329163 A1
(43) Pub. Date: Oct. 22, 2026

(54) REFLECTIVE MASK BLANK, REFLECTIVE MASK AND METHOD FOR MANUFACTURING THE SAME, AND METHOD FOR MANUFACTURING SEMICONDUCTOR DEVICE

(71) Applicant: HOYA CORPORATION, Tokyo (JP)

(72) Inventors: Kazutake TANIGUCHI, Tokyo (JP); Masanori NAKAGAWA, Tokyo (JP)

(73) Assignee: HOYA CORPORATION, Tokyo (JP)

(21) Appl. No.: 19/105,564

(22) PCT Filed: Aug. 23, 2023
(86) PCT No.: PCT/JP2023/030283

§ 371 Date: Feb. 21, 2025

(30) Foreign Application Priority Data
Aug. 30, 2022 (JP) 2022-136730

(51) Int. Cl. G03F 1/24; G03F 1/48; G03F 1/52; G03F 1/54; G03F 1/80

(52) U.S. Cl. CPC G03F 1/24; G03F 1/48; G03F 1/52; G03F 1/54; G03F 1/80

(57) ABSTRACT

A reflective mask blank includes a substrate, a multilayer reflective film provided above the substrate, an absorber film provided above the multilayer reflective film, and an etching mask film provided above the absorber film. The absorber film includes absorption layer, the etching mask film is provided in contact with the absorber film and includes an element X and oxygen (O), an oxygen concentration ratio obtained by dividing a content (at %) of oxygen (O) by a total content (at %) of the element X and oxygen (O) is defined in the etching mask film, an oxygen concentration ratio of the etching mask film on the absorption layer side is higher than an oxygen concentration ratio at a film thickness center of the etching mask film, and the element X includes one or more of tantalum (Ta) and silicon (Si).

### TECHNICAL FIELD

The present invention relates to a reflective mask blank that is an original plate for manufacturing an exposure mask used for manufacturing a semiconductor device or the like, a reflective mask and a method for manufacturing the same, and a method for manufacturing a semiconductor device.

### BACKGROUND ART

The type of light source in an exposure apparatus used for manufacturing a semiconductor device has developed with gradually shortening a wavelength, such as a g-ray with a wavelength of 436 nm, an i-ray with a wavelength of 365 nm, a KrF laser with a wavelength of 248 nm, and an ArF laser with a wavelength of 193 nm. EUV lithography using an extreme ultra violet (EUV) ray with a wavelength near 13.5 nm has been developed in order to achieve finer pattern transfer. In EUV lithography, a reflective mask is used because there are few materials transparent to EUV light. This reflective mask has a basic structure in which a multilayer reflective film that reflects exposure light is formed on a low thermal expansion substrate and a desired transfer pattern is formed on a protective film for protecting the multilayer reflective film. In addition, from a viewpoint of a configuration of the transfer pattern, typical examples of the mask structure include a binary reflection mask having a relatively thick absorber pattern that sufficiently absorbs EUV light and a phase shift type reflection mask (half-tone phase shift type reflection mask) having a relatively thin absorber pattern that reduces EUV light by light absorption and generates reflected light having a phase substantially inverted (phase inverted at approximately 180 degrees) with respect to reflected light from the multilayer reflective film. The phase shift type reflective mask (halftone phase shift type reflective mask) has a resolution improving effect because a high transfer optical image contrast can be obtained by a phase shift effect like a transmission type optical phase shift mask. In addition, since an absorber pattern (phase shift pattern) of the phase shift type reflection mask has a thin film thickness, a fine and highly accurate phase shift pattern can be formed.

A reflective mask blank, which is an original plate for manufacturing a reflective mask, typically includes, on a substrate, a multilayer reflective film for reflecting exposure light, a protective film for protecting the multilayer reflective film from dry etching, defect correction using an electron beam (EB), or the like, an absorber film for forming an absorber pattern, and an etching mask film serving as a mask for pattern-etching the absorber film. In addition, in a case where an etching selective ratio between the absorber film that absorbs/attenuates EUV light and the protective film is not sufficiently high, a mainstream absorber film includes a buffer layer that protects the multilayer reflective film located below such that the multilayer reflective film is not damaged by dry etching during pattern formation.

By the way, in EUV lithography, a projection optical system including a large number of reflecting mirrors is used due to light transmittance. In such a projection optical system, EUV light is made obliquely incident on a reflective mask to cause these reflecting mirrors not to block projection light (exposure light). As a numerical aperture (NA) of the projection optical system is improved, consideration is being made to make an incident angle of exposure light a larger oblique incident angle (for example, 6° or more). However, in the projection optical system in which exposure light is obliquely incident on a mask surface, there is a problem of a shadowing effect that reduces accuracy of dimensions and position of a pattern to be transferred and formed. The shadowing effect is mainly caused by a three-dimensional structure of an

absorber pattern. Therefore, the shadowing effect can be reduced by making the absorber film as thin as possible. However, when the absorber film is thinned, exposure light cannot be sufficiently absorbed, and undesirable reflected light from an absorber pattern may adversely affect transfer accuracy, and there is a limit to thinning the absorber film.

In view of such a background, for example, Patent Document 1 discloses a reflective mask blank in which an absorber film includes a buffer layer and an absorption layer disposed on the buffer layer, the buffer layer is made of a material containing tantalum (Ta) or silicon (Si), and the absorption layer is made of a material containing chromium (Cr) having a relatively high extinction coefficient of EUV light (for example, a wavelength is 13.5 nm). With this configuration, it has been confirmed that an absorber pattern in which a reflectance of EUV light is 2% or less can be achieved even when the film thickness of the absorber film is thinner than that in related art.

Furthermore, Patent Document 1 discloses that the etching mask film is made of a material containing tantalum (Ta) or silicon (Si) of the same type as the buffer layer in order to be able to remove the etching mask film simultaneously when the buffer layer is patterned.

For example, when an etching mask film containing tantalum (Ta) is patterned, a fluorine (F)-based gas is used. However, when a fluorine (F)-based gas is used for dry etching of the etching mask film, an etching rate of a resist film is relatively high, and therefore it is difficult to finely pattern the etching mask film with high accuracy only with the resist film. In this regard, for example, Patent Document 2 describes a photomask including a hard mask layer as an etching mask film on an absorption layer containing chromium (Cr), the hard mask layer including a tantalum (Ta)-based first hard mask layer for patterning the absorption layer and a chromium (Cr)-based second hard mask layer for patterning the first hard mask layer.

### PRIOR ART DOCUMENTS

### Patent Documents

Patent Document 1: WO 2020/175354 A
Patent Document 2: US 2021/0405519 A

### SUMMARY OF INVENTION

### Technical Problem

In general, in order to suppress a critical dimension (CD) change in a dry etching process using an etching gas containing oxygen, an etching mask film is preferably made of an oxide. On the other hand, for example, when an oxygen concentration contained in a tantalum-based etching mask film is high, electrical resistivity increases, and excessive charging occurs in a process of manufacturing a reflective mask blank and a reflective mask, resulting in a problem that a frequency of occurrence of fatal defects caused by electrostatic breakdown increases.

The present invention has been made in view of the above problems, and an object of the present invention is to provide a reflective mask blank that prevents occurrence of electrostatic breakdown while suppressing a CD change in a dry etching process by making an oxygen concentration ratio at a film thickness center of an etching mask film lower than an oxygen concentration ratio at least at a bottom of the etching mask film, a reflective mask prepared with the reflective mask blank, a method for manufacturing the reflective mask, and a method for manufacturing a semiconductor device using the reflective mask.

### Solution to Problem

In order to solve the above problems, the present invention has the following configurations.

### (Configuration 1)

Configuration 1 of the present invention is a reflective mask blank comprising a multilayer reflective film, an absorber film, and an etching mask film in this order, in which
the absorber film comprises a buffer layer and an absorption layer having etching resistance to the buffer layer,
the etching mask film has etching resistance to the absorption layer and comprises an element X and oxygen (O),
when an oxygen concentration ratio obtained by dividing the content (at %) of oxygen (O) by the total content of the element X and oxygen (O) is defined in the etching mask film, an oxygen concentration ratio of the etching mask film on the absorption layer side is higher than an oxygen concentration ratio at a film thickness center of the etching mask film, and
the element X comprises at least one selected from tantalum (Ta) and silicon (Si).

### (Configuration 2)

Configuration 2 of the present invention is the reflective mask blank according to Configuration 1, in which an oxygen concentration ratio of the etching mask film on a surface side opposite to the absorption layer is higher than the oxygen concentration ratio at the film thickness center of the etching mask film.

### (Configuration 3)

Configuration 3 of the present invention is the reflective mask blank according to Configuration 1 or 2, in which the etching mask film has a film thickness of 6 nm to 30 nm.

### (Configuration 4)

Configuration 4 of the present invention is the reflective mask blank according to any one of Configurations 1 to 3, in which a ratio of the film thickness of the etching mask film to the film thickness of the buffer layer is 0.1 to 15.

### (Configuration 5)

Configuration 5 of the present invention is the reflective mask blank according to any of Configurations 1 to 4, comprising a second etching mask film on the etching mask film as a first etching mask film, in which the second etching mask film comprises chromium (Cr).

### (Configuration 6)

Configuration 6 of the present invention is the reflective mask blank according to any one of Configurations 1 to 5, in which the buffer layer comprises at least one selected from tantalum (Ta) and silicon (Si).

### (Configuration 7)

Configuration 7 of the present invention is the reflective mask blank according to any one of Configurations 1 to 6, in which the absorption layer comprises at least one selected from chromium (Cr) and ruthenium (Ru).

### (Configuration 8)

Configuration 8 of the present invention is the reflective mask blank according to any one of Configurations 1 to 7, comprising a protective film between the multilayer reflective film and the absorber film.

### (Configuration 9)

Configuration 9 of the present invention is a reflective mask comprising an absorber pattern in which the absorber film in the reflective mask blank according to any one of Configurations 1 to 8 is patterned.

### (Configuration 10)

Configuration 10 of the present invention is a method for manufacturing a reflective mask from the reflective mask blank according to any one of Configurations 1 to 8, the method comprising: dry-etching the etching mask film to form an etching mask film pattern; and patterning the absorber film using the etching mask film pattern as a mask.

### (Configuration 11)

Configuration 11 of the present invention is a method for manufacturing a semiconductor device, the method comprising setting the reflective mask according to Configuration 9 in an exposure apparatus and transferring a transfer pattern onto a resist film formed on a transferred substrate.

### Advantageous Effects of Invention

According to the present invention, it is possible to provide a reflective mask blank and a method for manufacturing a reflective mask, capable of preventing occurrence of fatal defects caused by electrostatic breakdown while suppressing a CD change in a dry etching process by making an oxygen concentration ratio at a film thickness center of an etching mask film lower than an oxygen concentration ratio at least at a bottom of the etching mask film. In addition, according to the present invention, since the etching mask film has a predetermined oxygen concentration ratio, an etching rate of the etching mask film can be adjusted according to pattern etching of an absorber film. Therefore, it is possible to provide a reflective mask blank and a method for manufacturing a reflective mask that do not damage a surface of an absorber film or a protective film that protects a multilayer reflective film in a dry etching process. In addition, according to the present invention, it is possible to provide a reflective mask suppressing a CD change in an etching process and having a fine and highly accurate absorber pattern. In addition, according to the present invention, it is possible to manufacture a semiconductor device in which a fine and highly accurate transfer pattern is formed by using the reflective mask.

### BRIEF DESCRIPTION OF DRAWINGS

FIG. 1 is a schematic cross-sectional view for describing a schematic configuration of a reflective mask blank according to an embodiment of the present invention.

FIG. 2 is a schematic cross-sectional view for describing an example of a layer configuration of the reflective mask blank.

FIG. 3 is a schematic cross-sectional view for describing another example of the layer configuration of the reflective mask blank.

FIG. 4A is a schematic cross-sectional view for describing a process of preparing a reflective mask from a reflective mask blank.

FIG. 4B is a subsequent schematic cross-sectional view for describing the process of preparing the reflective mask from the reflective mask blank.

FIG. 4C is a subsequent schematic cross-sectional view for describing the process of preparing the reflective mask from the reflective mask blank.

FIG. 4D is a subsequent schematic cross-sectional view for describing the process of preparing the reflective mask from the reflective mask blank.

FIG. 4E is a subsequent schematic cross-sectional view for describing the process of preparing the reflective mask from the reflective mask blank.

FIG. 4F is a subsequent schematic cross-sectional view for describing the process of preparing the reflective mask from the reflective mask blank.

FIG. 4G is a subsequent schematic cross-sectional view for describing the process of preparing the reflective mask from the reflective mask blank.

### DESCRIPTION OF EMBODIMENTS

Hereinafter, an embodiment of the present invention will be specifically described with reference to the drawings. Note that the following embodiment is one mode for embodying the present invention and does not limit the present invention within a scope thereof. In addition, in the drawings, the same or corresponding parts are denoted by the same reference signs, and description thereof may be simplified or omitted.

In the present specification, “on” a substrate or a film includes not only a case of being in contact with a top surface of the substrate or the film but also a case of being not in contact with the top surface of the substrate or the film. That is, “on” a substrate or a film includes a case where a new film is formed above the substrate or the film, and a case where another film is interposed between the substrate or the film. In addition, “on” does not necessarily mean an upper side in a vertical direction, but merely indicates a relative positional relationship of a substrate or a film in a thickness direction.

### <Configuration of Reflective Mask Blank>

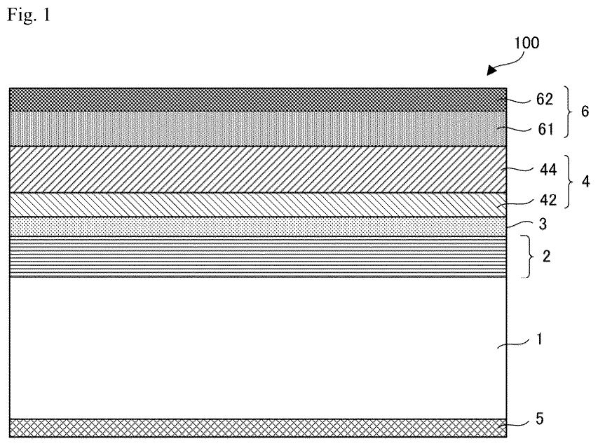

FIG. 1 is a schematic cross-sectional view for describing a schematic configuration of a reflective mask blank 100 according to an embodiment of the present invention. As illustrated in FIG. 1, the reflective mask blank 100 includes a substrate 1, a multilayer reflective film 2 that is formed on a first main surface (front surface) side and reflects EUV light that is exposure light, a protective film 3 disposed for protecting the multilayer reflective film 2, an absorber film 4 that absorbs EUV light, and an etching mask film 6, and these films are layered in this order. In the reflective mask blank 100 of the present embodiment, the absorber film 4 includes a buffer layer 42 and an absorption layer 44 disposed on the buffer layer 42. In addition, a conductive back film 5 for electrostatic chuck is formed on a side of a second main surface (back surface) side of the substrate 1.

The reflective mask blank 100 can include a configuration in which the conductive back film 5 is not formed. In addition, the above reflective mask blank 100 can include a configuration of a mask blank with a resist film in which a resist film 11 is formed on the etching mask film 6.

Hereinafter, a configuration of each layer of the reflective mask blank 100 according to an embodiment of the present invention will be specifically described.

### <<Substrate>>

As the substrate 1, one having a low thermal expansion coefficient within a range of 0±5 ppb/°C is preferably used in order to prevent distortion of a transfer pattern (absorber pattern described later) due to heat at the time of exposure to EUV light. As a material having a low thermal expansion coefficient within this range, for example, SiO₂—TiO₂-based glass, multicomponent-based glass ceramic, or the like can be used.

A first main surface of the substrate 1 on a side where a transfer pattern is formed has been subjected to surface processing so as to have a high flatness from a viewpoint of obtaining at least pattern transfer accuracy and position accuracy. In a case of EUV exposure, flatness in an area of 132 mm×132 mm of the main surface on the side of the substrate 1 where a transfer pattern is formed is preferably 0.1 μm or less, more preferably 0.05 μm or less, and particularly preferably 0.03 μm or less. In addition, a second main surface on a side opposite to the side where the absorber film 4 is formed is a surface to be electrostatically chucked at the time of setting on an exposure apparatus, and in an area of 142 mm×142 mm of the second main surface, flatness is preferably 0.1 μm or less, more preferably 0.05 μm or less, and particularly preferably 0.03 μm or less.

In addition, the first main surface of the substrate 1 where a transfer pattern is formed preferably has a surface roughness (surface smoothness) of 0.1 nm or less in terms of root mean square roughness (Rq). Note that the surface roughness can be measured with an atomic force microscope.

Furthermore, the substrate 1 preferably has a high rigidity in order to prevent deformation due to film stress of a film (such as the multilayer reflective film 2) formed on the substrate 1. In particular, the substrate 1 preferably has a high Young's modulus of 65 GPa or more.

### <<Multilayer Reflective Film>>

The multilayer reflective film 2 has a multilayer structure in which a plurality of layers mainly containing elements having different refractive indices is periodically layered. In general, the multilayer reflective film 2 is formed of a multilayer film in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods. In order to form the multilayer reflective film 2, the high refractive index layer and the low refractive index layer may be layered in this order from the substrate 1 side for a plurality of periods. In this case, one (high refractive index layer/low refractive index layer) stack is one period.

Note that an uppermost layer of the multilayer reflective film 2, that is, a surface layer of the multilayer reflective film 2 on a side opposite to the substrate 1 is preferably formed of the high refractive index layer. When the high refractive index layer and the low refractive index layer are built up in this order from the substrate 1 side, the low refractive index layer forms the uppermost layer. However, when the low refractive index layer forms a surface of the multilayer reflective film 2, the reflectance of the surface of the multilayer reflective film 2 is reduced due to easy oxidation of the low refractive index layer. Therefore, the high refractive index layer is preferably formed on the low refractive index layer. Meanwhile, when the low refractive index layer and the high refractive index layer are built up in this order from the substrate 1 side, the high refractive index layer forms the uppermost layer. In this case, the high refractive index layer as the uppermost layer is a surface of the multilayer reflective film 2.

The high refractive index layer included in the multilayer reflective film 2 is a layer made of a material containing, for example, Si. The high refractive index layer may contain a simple substance of Si or a Si compound. The Si compound may be a Si compound containing silicon (Si), boron (B), carbon (C), nitrogen (N), oxygen (O), and hydrogen (H). By using the layer containing Si as the high refractive index layer, an EUV lithography reflective mask 200 for having an excellent EUV light reflectance can be obtained.

The low refractive index layer included in the multilayer reflective film 2 is a layer made of a material containing a transition metal. As the transition metal contained in the low refractive index layer, a metal simple substance selected from molybdenum (Mo), ruthenium (Ru), rhodium (Rh), and platinum (Pt), or an alloy thereof is used.

For example, as the multilayer reflective film 2 for EUV light having a wavelength of 13 to 14 nm, a Mo/Si multilayer film in which a Mo film and a Si film are alternately layered for about 40 to 60 periods can be preferably used.

The reflectance of such a multilayer reflective film 2 alone is, for example, 65% or more. An upper limit of the reflectance of the multilayer reflective film 2 is, for example, 73%. Note that the thickness and period of each layer included in the multilayer reflective film 2 can be selected so as to satisfy Bragg's law. Note that the thickness and period of each constituent layer of the multilayer reflective film 2 only need to be appropriately selected according to an exposure wavelength and are selected so as to satisfy the Bragg reflection law. In the multilayer reflective film 2, there are a plurality of high refractive index layers and a plurality of low refractive index layers, but a thickness does not need to be the same between the high refractive index layers and between the low refractive index layers. In addition, the film thickness of the Si layer on the outermost surface of the multilayer reflective film 2 can be adjusted within a range that does not lower the reflectance. The film thickness of the Si (high refractive index layer) of the outermost surface can be 3 nm to 10 nm.

The multilayer reflective film 2 can be formed by an ion beam sputtering method. For example, when the multilayer reflective film 2 is a Mo/Si multilayer film, a Mo film having a film thickness of about 3 nm is formed on the substrate 1 by an ion beam sputtering method using a Mo target. Next, a Si film having a film thickness of about 4 nm is formed using a Si target. By repeating such an operation, the multilayer reflective film 2 in which the Mo/Si film is layered for 40 to 60 periods can be formed. At this time, a surface layer of the multilayer reflective film 2 on a side opposite to the substrate 1 is a layer containing Si (Si film). The Mo/Si film in one period has a thickness of 7 nm. In addition, when the multilayer reflective film 2 is formed, the multilayer reflective film 2 may be formed by supplying krypton (Kr) ion particles from an ion source and performing ion beam sputtering.

### <<Protective Film>>

The reflective mask blank 100 preferably includes the protective film 3 between the multilayer reflective film 2 and the absorber film 4. The protective film 3 is formed on the multilayer reflective film 2, and it is thereby possible to suppress damage to a surface of the multilayer reflective film 2 when the reflective mask 200 (EUV mask) is manufactured using the reflective mask blank 100. Therefore, a reflectance characteristic for EUV light is favorable.

The protective film 3 is formed on the multilayer reflective film 2 in order to protect the multilayer reflective film 2 from dry etching and cleaning in a process for manufacturing the reflective mask 200 described later. In addition, the protective film 3 also protects the multilayer reflective film 2 when a black defect of an absorber pattern 4a is corrected using an electron beam (EB). The protective film 3 is made of a material having resistance to an etchant, a cleaning liquid, and the like.

Here, FIG. 1 illustrates a case where the protective film 3 is a single layer, but the protective film 3 can have a stack of two or more layers.

The protective film 3 can contain, for example, a material containing Ru as a main component. That is, examples of the material of the protective film 3 include a Ru metal simple substance, a Rh metal simple substance, a Ru alloy containing Ru and at least one metal selected from titanium (Ti), niobium (Nb), rhodium (Rh), molybdenum (Mo), zirconium (Zr), yttrium (Y), boron (B), lanthanum (La), cobalt (Co), rhenium (Re), and the like, and a material containing a Ru metal simple substance, a Rh metal simple substance, or a Ru alloy, and nitrogen (N).

Such a protective film 3 is particularly effective when the buffer layer 42 in the absorber film 4 is patterned by dry etching with a fluorine-based gas (F-based gas) or a chlorine-based gas (Cl-based gas) not containing oxygen. The protective film 3 is preferably made of a material having an etching selective ratio of 1.5 or more, preferably 3 or more, the etching selective ratio being an etching selective ratio of the buffer layer 42 to the protective film 3 in dry etching using a fluorine-based gas or a chlorine-based gas (etching rate of buffer layer 42/etching rate of protective film 3).

The thickness of the protective film 3 is not particularly limited as long as a function as the protective film 3 can be achieved. The thickness of the protective film 3 is preferably 1.0 nm to 8.0 nm, and more preferably 1.5 nm to 6.0 nm from a viewpoint of the reflectance of EUV light.

Examples of a method for forming the protective film 3 include an ion beam sputtering method, a magnetron sputtering method, a reactive sputtering method, a vapor phase growth method (CVD), and a vacuum vapor deposition method. The protective film 3 may be continuously formed by an ion beam sputtering method after the multilayer reflective film 2 is formed.

### <<Absorber Film>>

The absorber film 4 for absorbing or extinguishing EUV light is formed on the multilayer reflective film 2 or the protective film 3 described above. For example, in a reflective mask blank 100 for preparing a binary reflective mask, the film thickness of the absorber film 4 is preferably as thin as possible in order to obtain a fine and highly accurate absorber pattern (transfer pattern). Therefore, a material of the absorber film 4 preferably has a high absorptivity of EUV light (small reflectance). In addition, also in a reflective mask blank 100 for preparing a phase shift type reflective mask, the absorber film 4 is preferably made of a material having a high absorptivity in order to reverse a phase of EUV reflected light with a relatively thin absorber pattern.

Furthermore, in the reflective mask blank 100 according to the present embodiment, the absorber film 4 includes the buffer layer 42 and the absorption layer 44 disposed on the buffer layer 42 (on a side opposite to the substrate 1).

A material of the absorption layer 44 in the absorber film 4 of the present embodiment can be a material that has a function of absorbing EUV light, can be processed by etching or the like (preferably, can be etched by dry etching with a chlorine (Cl)-based gas and/or a fluorine (F)-based gas), and has a high etching selective ratio to the protective film 3 and the etching mask film 6 described later. As a material having such a function, at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), an alloy containing two or more metals selected therefrom, or a compound thereof can be preferably used. The compound may contain the above metal or alloy and oxygen (O), nitrogen (N), carbon (C), and/or boron (B).

The material of the absorption layer 44 preferably contains, for example, chromium (Cr) and/or ruthenium (Ru). When a thin film containing Cr or Ru is disposed in contact with a surface of the protective film 3 containing Ru as a main component, there is a problem that an etching selective ratio between the absorption layer 44 and the protective film 3 is not high. Therefore, in the reflective mask blank 100 according to the present embodiment, the buffer layer 42 made of a material containing at least one selected from tantalum (Ta) and silicon (Si) is disposed between the absorption layer 44 and the protective film 3.

In an embodiment, a material of the buffer layer 42 contains tantalum (Ta). In addition, the material of the buffer layer 42 preferably contains tantalum (Ta) and one or more elements selected from oxygen (O), nitrogen (N), and boron (B). Specific examples of the material of the buffer layer 42 containing tantalum (Ta) include Ta, TaN, TaO, TaON, TaB, TaBN, TaBO, TaBON, and the like.

As the material of the buffer layer 42 containing tantalum (Ta), at least one metal selected from palladium (Pd), silver (Ag), platinum (Pt), gold (Au), iridium (Ir), tungsten (W), chromium (Cr), cobalt (Co), manganese (Mn), tin (Sn), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), or two or more metals selected from these metals may be further contained.

When the material of the buffer layer 42 is a material containing Ta and at least one element selected from N and B, the Ta content in the buffer layer 42 is 50 at % or more, and can be 70 at % or more. The Ta content in the buffer layer 42 is 95 at % or less, and can be 65 at % or less. The total content of N and B in the buffer layer 42 is 50 at % or less, and can be 30 at % or less. The total content of N and B in the buffer layer 42 can be 5 at % or more. The content of N is preferably smaller than the content of B. This is because as the content of N is smaller, an etching rate with a chlorine gas is higher and the buffer layer 42 is more easily removed.

When the material of the buffer layer 42 is a material containing Ta and O, the Ta content in the buffer layer 42 is 50 at % or more, and can be 70 at % or more. The Ta content in the buffer layer 42 is 95 at % or less, and can be 65 at % or less. The O content in the buffer layer 42 is 70 at % or less, and can be 60 at % or less. The O content in the buffer layer 42 is 10 at % or more, and can be 20 at % or more from a viewpoint of ease of etching.

In another embodiment, the buffer layer 42 may be made of a material containing silicon (Si). In addition, the material of the buffer layer 42 preferably contains silicon (Si) and at least one element selected from oxygen (O), nitrogen (N), carbon (C), and hydrogen (H).

Specific examples of the material containing silicon include SiO, SiN, SiON, SiC, SiCO, SiCN, SiCON, MoSi, MoSiO, MoSiN, MoSiON, and the like. SiO, SiN, or SiON is preferably used as the material containing Si. Note that the material can contain a metalloid or metal other than Si within a range in which the effects of the present invention can be obtained. In addition, molybdenum silicide can be used as the metal Si compound.

The film thickness of the buffer layer 42 may be about the same as or smaller than that of the etching mask film 6 described later as long as the protective film 3 is not damaged at the time of etching the absorber film 4. Specifically, the film thickness of the buffer layer 42 is preferably 2 nm to 50 nm, and can be 4 nm to 30 nm.

The buffer layer 42 is made of a material containing at least one selected from tantalum (Ta) and silicon (Si) as described above, and can be thereby etched with, for example, a fluorine-based gas or a chlorine-based gas not containing oxygen. In addition, the buffer layer 42 made of such a material can have sufficient etching resistance to the protective film 3 containing Ru as a main component.

Next, the absorption layer 44 disposed in contact with an upper surface of the buffer layer 42 can be made of a material containing at least one selected from chromium (Cr) and ruthenium (Ru) as described in detail below. As a result, the absorption layer 44 has etching resistance to the buffer layer 42, and can satisfy optical characteristics as an absorber film (phase shift film) even if the film thickness of the absorption layer 44 is made thinner than that in related art.

Here, layer A having “etching resistance” to layer B means that an etching rate of layer B is sufficiently higher than an etching rate of layer A when layer B is etched using layer A as a mask. More specifically, when an etching selective ratio of layer B to layer A, defined by a formula of etching rate of layer B/etching rate of layer A is 1.5 or more, and preferably 3 or more, it can be said that layer A has “etching resistance” to layer B.

In one embodiment, the material of the absorption layer 44 is a chromium (Cr) simple substance or a Cr compound containing chromium (Cr) and at least one element selected from nitrogen (N), oxygen (O), and carbon (C). Examples of the Cr compound include CrN, CrC, CrON, CrCO, CrCN, CrCON, CrBN, CrBC, CrBON, CrBCN, CrBOCN, and the like. In order to increase an extinction coefficient of the absorption layer 44, the material of the absorption layer 44 can be a material containing no oxygen. In this case, it is also possible to increase an etching selective ratio regarding a chlorine-based gas. Examples of the Cr compound containing no oxygen include CrN, CrC, CrCN, CrBN, CrBC, CrBCN, and the like. The Cr content of the Cr compound is preferably 50 at % or more and less than 100 at %, and more preferably 80 at % or more and less than 100 at %. In addition, in the present specification, “containing no oxygen” or “containing substantially no oxygen” corresponds to a compound having an oxygen content of 10 at % or less, preferably 5 at % or less.

In another embodiment, the absorption layer 44 may be made of a material containing a ruthenium (Ru) simple substance or a Ru compound containing ruthenium (Ru) and at least one element selected from nitrogen (N) and oxygen (O). Examples of the Ru compound include RuN, RuON, RuO, and the like.

In addition, the material of the absorption layer 44 may be a RuCr-based compound containing ruthenium (Ru) and chromium (Cr). The Ru-based compound tends to have a crystallized structure and adversely affects processing performance. That is, crystallized metal crystal particles are likely to increase a sidewall roughness when forming an absorber pattern, and thus the absorber film 4 is preferably amorphous. By adding chromium (Cr) to ruthenium (Ru) as the material of the absorption layer 44, the crystal structure can be made amorphous, and processing characteristics can be improved. In addition, by further inclusion of at least one element selected from nitrogen (N) and oxygen (O) in addition to ruthenium (Ru) and chromium (Cr), the crystal structure can be further made amorphous. Examples of the RuCr-based compound include RuCrN, RuCrON, RuCrO, and the like. A composition range (atomic ratio) of Ru and Cr can be Ru:Cr=40:1 to 1:20, and can be 40:1 to 3:7.

In addition, the material of the absorption layer 44 may be a RuTa-based compound or a RuPt-based compound containing ruthenium (Ru) and tantalum (Ta) or platinum (Pt). The RuTa-based compound or the RuPt-based compound may further contain at least one element selected from nitrogen (N), oxygen (O), and boron (B). Examples of the RuTa-based compound include RuTaN, RuTaON, RuTaO, RuTaB, RuTaBN, RuTaBO, RuTaBNO, and the like. Examples of the RuPt-based compound include RuPtN, RuPtON, RuPtO, RuPtB, RuPtBN, RuPtBO, RuPtBNO, and the like. The Ru content of the RuTa-based compound is preferably 30 at % or more and less than 100 at %, and more preferably 40 at % or more and less than 100 at %. The Ru content of the RuPt-based compound is preferably 30 at % or more and less than 100 at %, and more preferably 40 at % or more and less than 100 at %.

The absorption layer 44 containing at least one element selected from chromium (Cr) and ruthenium (Ru) can be etched with a mixed gas of a chlorine-based gas and an oxygen gas. In addition, the absorption layer 44 may be etched with a mixed gas of a fluorine-based gas and an oxygen gas.

The film thickness of the absorption layer 44 is preferably 10 nm to 70 nm, and more preferably 20 nm to 60 nm. In addition, the entire film thickness of the absorber film 4 including the buffer layer 42 and the absorption layer 44 is preferably 15 nm to 75 nm, and more preferably 25 nm to 65 nm.

In addition, an oxide layer may be formed on a surface of the absorber film 4 (absorption layer 44). The oxide layer is formed on the surface of the absorber film 4 (absorption layer 44), whereby cleaning resistance of the absorber pattern 4a of the obtained reflective mask 200 can be improved. The thickness of the oxide layer is preferably 1.0 nm or more, and more preferably 1.5 nm or more. In addition, the thickness of the oxide layer is preferably 5 nm or less, and more preferably 3 nm or less. When the thickness of the oxide layer is less than 1.0 nm, an effect cannot be expected because the oxide layer is too thin, and when the thickness exceeds 5 nm, an influence on a surface reflectance with respect to mask inspection light is large, and it is difficult to perform control for obtaining a predetermined surface reflectance.

Examples of a method for forming the oxide layer include performing a warm water treatment, an ozone water treatment, a heat treatment in a gas containing oxygen, an ultraviolet irradiation treatment in a gas containing oxygen, an O₂ plasma treatment, and the like on the mask blank after the absorber film 4 (absorption layer 44) is formed. In addition, when a surface of the absorber film 4 (absorption layer 44) is exposed to the atmosphere after the absorber film 4 (absorption layer 44) is formed, an oxide layer due to natural oxidation may be formed on the surface layer. In particular, in some cases, an oxide layer having a film thickness of 1 to 2 nm is formed.

### <<Etching Mask Film>>

In the reflective mask blank 100 of the present embodiment, the etching mask film 6 to be a mask (also referred to as a “hard mask”) for patterning the absorber film 4 is formed. The etching mask film 6 is disposed in contact with an upper surface of the absorption layer 44 described above, and includes an etching mask film 61 having etching resistance to the absorption layer 44. In addition, the reflective mask blank 100 may include the etching mask film 61 disposed in contact with the absorption layer 44 as a first etching mask film, and may further include a second etching mask film 62 having etching resistance to the first etching mask film 61.

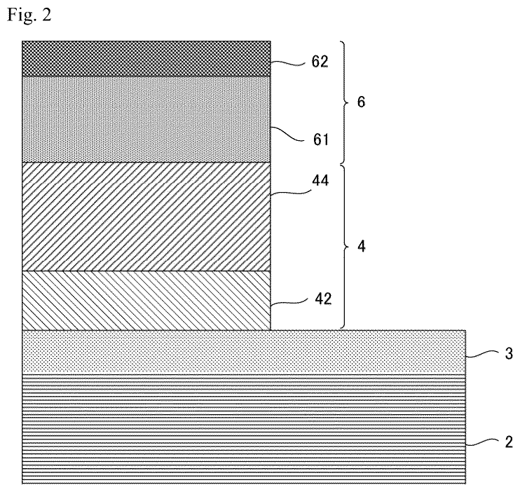

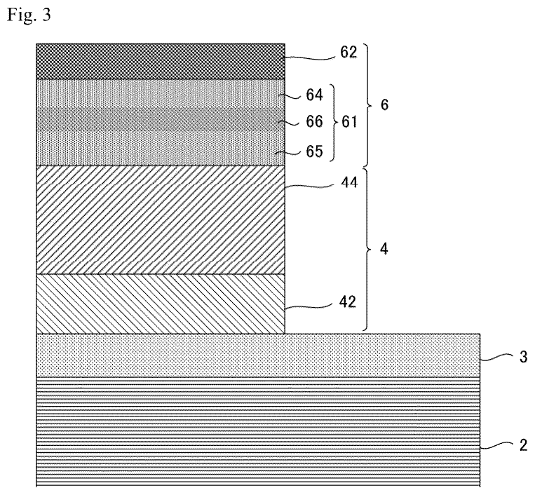

For example, as in a layer configuration example 1 illustrated in FIG. 2, the first etching mask film 61 is made of a composition-gradient film containing a predetermined element X and oxygen (O). Furthermore, the first etching mask film 61 may partially include layers 64 and 65 containing a predetermined element X and oxygen (O) and a layer 66 substantially containing no oxygen (O), for example, as in a layer configuration example 2 illustrated in FIG. 3.

In any of the above-described layer configuration examples 1 and 2, the predetermined element X contained in the first etching mask film 61 contains at least one element selected from tantalum (Ta) and silicon (Si). The material of the first etching mask film 61 preferably contains the above-described element X and at least one element selected from oxygen (O), nitrogen (N), and boron (B). Specific examples thereof include TaO, TaON, TaBO, TaBON, SiO, SiON, SiBO, SiBON, and the like.

When the material of the first etching mask film 61 is a material containing Ta and O, the Ta content in the first etching mask film 61 is 50 at % or more, and can be 70 at % or more. The Ta content in the first etching mask film 61 is 95 at % or less, and can be 65 at % or less. The O content in the first etching mask film 61 is 70 at % or less, and can be 60 at % or less. The O content in the first etching mask film 61 is 2 at % or more, and can be 6 at % or more.

When the material of the first etching mask film 61 is a material containing Si and O, the Si content in the first etching mask film 61 is 25 at % or more, and can be 40 at % or more. The Si content in the first etching mask film 61 is 80 at % or less, and can be 60 at % or less. The O content in the first etching mask film 61 is 70 at % or less, and can be 60 at % or less. The O content in the first etching mask film 61 is 10 at % or more, and can be 20 at % or more.

In addition, as described above, the material of the first etching mask film 61 preferably contains the predetermined element X and also contains oxygen (O) with a predetermined concentration ratio profile in a film thickness direction. The first etching mask film 61 has the predetermined oxygen concentration ratio, whereby it is possible to prevent damage to the protective film 3 (the multilayer reflective film 2 in a case where there is no protective film 3) or the absorption layer 44 in a dry etching process of the buffer layer 42 as described later.

The first etching mask film 61 can be etched and removed with a fluorine-based gas by containing at least one element selected from tantalum (Ta) and silicon (Si). As the fluorine-based gas, CF₄, CHF₃, C₂F₆, C₃F₆, C₄F₆, C₄F₈, CH₂F₂, CH₃F, C₃F₈, SF₆, F₂, and the like can be used. In addition, each of these etching gases can further contain an inert gas such as He and/or Ar as necessary.

In the present specification, an existing oxygen concentration ratio to the total content of the at least one element X in the first etching mask film 61 is defined by the following formula (1).

$$\begin{matrix}[ Mathematical Formula 1 ] & \\ Oxygen concentration ratio ( \% ) = \frac{O}{X + O} \times 100 & ( 1 )\end{matrix}$$

Here, in the above definition formula (1), a variable X represents the total content (at %) of metal elements constituting the first etching mask film 61, and a variable O represents the content (at %) of oxygen.

The content of each component constituting the etching mask film 6 can be measured by energy dispersive X-ray spectroscopy (EDX) using a scanning transmission electron microscope (STEM).

In the reflective mask blank 100 according to a preferable embodiment of the present invention, an oxygen concentration ratio of the first etching mask film 61 on the absorption layer 44 side is higher than an oxygen concentration ratio at a film thickness center of the first etching mask film 61. In addition, an oxygen concentration ratio of the first etching mask film 61 on a side opposite to the absorption layer 44 is preferably higher than the oxygen concentration ratio at the film thickness center of the first etching mask film 61. By setting oxygen concentration ratios at a surface layer and a bottom of the first etching mask film 61 to a predetermined value or more and setting an oxygen concentration ratio at a film thickness center of the first etching mask film 61 to a predetermined value or less, it is easier to prevent occurrence of electrostatic breakdown while suppressing a CD change in a dry etching process.

In addition, the oxygen concentration ratio of the first etching mask film 61 on the absorption layer 44 side can be the same as or higher than the oxygen concentration ratio of the first etching mask film 61 on a side opposite to the absorption layer 44. When the first etching mask film 61 is made of a material containing Ta, a selective ratio between the first etching mask film 61 and the absorption layer 44 can be increased in etching with a fluorine-based gas.

In addition, the oxygen concentration ratio of the first etching mask film 61 on a side opposite to the absorption layer 44 can be higher than the oxygen concentration ratio of the first etching mask film 61 on the absorption layer 44 side. In this case, it is possible to further suppress oxidation expansion that occurs when the second etching mask film 62 is etched with a chlorine-based gas containing an oxygen gas, and it is possible to suppress a CD change caused by thickening of the first etching mask film 61.

These characteristics can be defined by a magnitude relationship among an oxygen concentration ratio at an interface position x1 between the first etching mask film 61 and the absorption layer 44, an oxygen concentration ratio at an interface position x2 between the first etching mask film 61 and the second etching mask film 62 or a surface position x2 of the first etching mask film 61, and an oxygen concentration ratio at a center position x3 of the first etching mask film 61 in a film thickness direction.

That is, when these are expressed by a comparative formula,
O/(X+O) ratio at film thickness center x3<O/(X+O) ratio at interface x1; and
O/(X+O) ratio at film thickness center x3<O/(X+O) ratio at interface (surface) x2
are preferably satisfied.

In addition, in order to increase a selective ratio between the first etching mask film 61 and the absorption layer 44, O/(X+O) ratio at interface (surface) x2≤O/(X+O) ratio at interface x1 can be satisfied. In addition, in order to suppress a CD change caused by thickening of the first etching mask film 61, O/(X+O) ratio at interface x1<O/(X+O) ratio at interface (surface) x2 can be satisfied.

In a preferable embodiment of the reflective mask blank 100, the oxygen concentration ratio (O/(X+O) ratio) at the film thickness center position x3 of the first etching mask film 61 is 70% or less, and can be 50% or less.

In addition, the oxygen concentration ratio (O/(X+O) ratio) at the interface position x1 between the first etching mask film 61 and the absorption layer 44 is 5% or more, and can be 10% or more. In addition, the (O/(X+O) ratio) is 90% or less, and can be 80% or less.

In addition, a difference of the oxygen concentration ratio (O/(X+O) ratio) at the interface position x1 with the absorption layer 44 from the oxygen concentration ratio (O/(X+O) ratio) at the center position x3 of the first etching mask film 61 is 5% or more, and can be 10% or more. In addition, the difference in (O/(X+O) ratio) is 85% or less, and can be 75% or less.

In addition, the oxygen concentration ratio (O/(X+O) ratio) at the interface position x2 between the first etching mask film 61 and the second etching mask film 62 or the surface position x2 of the first etching mask film 61 is 1% or more, and can be 5% or more. In addition, the (O/(X+O) ratio) is 85% or less, and can be 75% or less.

In addition, a difference of the oxygen concentration ratio (O/(X+O) ratio) at the interface position x2 between the first etching mask film 61 and the second etching mask film 62 or the surface position x2 of the first etching mask film 61 from the oxygen concentration ratio (O/(X+O) ratio) at the center position x3 of the first etching mask film 61 is 1% or more, and can be 5% or more. In addition, the difference in (O/(X+O) ratio) is 80% or less, and can be 70% or less.

According to the reflective mask blank 100 of the present embodiment, by reducing the oxygen concentration ratio (O/(X+O) ratio) at the center position x3 of the first etching mask film 61 to a predetermined value or less, it is possible to prevent occurrence of fatal defects caused by electrostatic breakdown while suppressing a CD change in a dry etching process. In addition, by defining the oxygen concentration ratio of the first etching mask film 61, an etching rate of the first etching mask film 61 can be adjusted according to a progress of pattern etching of the buffer layer 42, and it is thereby possible to suppress damage to the protective film 3 or the absorption layer 44 in a dry etching process of the buffer layer 42.

The magnitude relationship of the oxygen concentration ratio (O/(X+O) ratio) described above can also be evaluated by X-ray photoelectron spectroscopy (XPS) in addition to EDX. It is also possible to perform evaluation by combining these analysis results with a transmission electron microscope (TEM). In addition, it is possible to determine the interface positions x1 and x2 between the layers, the center position x3 of the first etching mask film 61, and the like by performing fitting processing on the data measured by these methods using a known approximation function.

Note that, in the present specification, regarding the magnitude relationship of the oxygen concentration ratio (O/(X+O) ratio) of the first etching mask film 61, a numerical value by EDX is described, and regarding the content of an element constituting each film, a numerical value by XPS is described.

Usually, in the vicinity of the interface between the first etching mask film 61 and the absorption layer 44, components (elements) of the layers are mutually diffused. Here, in order to determine the interface position x1 between the first etching mask film 61 and the absorption layer 44, a method for determining an inflection point x1 at which the total content of metal elements contained in the absorption layer 44 is inflated in the film thickness direction x as the interface position x1 is adopted. Specifically, the interface position x1 between the first etching mask film 61 and the absorption layer 44 can be measured as follows.

First, the total content (at %) of metal elements contained in the absorption layer 44 is measured in the film thickness direction x extending from the first etching mask film 61 to the absorption layer 44. Here, the total content of metal elements is a Cr content when the absorption layer 44 is, for example, made of CrN, and is a RuCr content when the absorption layer 44 is, for example, made of RuCrN. Next, a function y_abs (x) is obtained by curve-fitting the measured total content data.

For this curve fitting, a known approximation method using an S-shaped function can be adopted. The S-shaped approximation function is generally used to approximate an S-shaped profile. As the S-shaped approximation function, an odd function selected from a polynomial function having a third or higher degree, a sigmoid function, an error function, an exponential function, a sine function, and the like can be used.

In order to determine the interface position x1 between the first etching mask film 61 and the absorption layer 44, a range (x1a to x1b) in the film thickness direction x for curve-fitting the content of the metal element contained in the absorption layer 44 can be determined as follows.

A start point (x=x1a) of the fitting range in the first etching mask film 61 can be set at a position which is near the interface position x1 with the absorption layer 44 and where the total content (at %) of the elements X constituting the first etching mask film 61 is a maximum value. Here, the total content of the elements X is a Ta content when the first etching mask film 61 is, for example, made of TaBO, a Si content when the first etching mask film 61 is, for example, made of SiO, and a TaSi content when the first etching mask film 61 is, for example, made of TaSiO.

An end point (x=x1b) of the fitting range in the absorption layer 44 can be set at a position which is near the interface position x1 with the first etching mask film 61 and where the total content (at %) of the metal elements constituting the absorption layer 44 is a maximum value.

The inflection point x1 of the total content of the metal elements constituting the absorption layer 44 can be obtained as a solution of the following second derivative equation (2) in which a value obtained by second-order differentiation of y_abs (x) is zero.

$$\begin{matrix}[ Mathematical Formula 2 ] & \\ \frac{{d}^{2}}{{dx}^{2}} y\_abs ( x ) = 0 & ( 2 )\end{matrix}$$

Note that when there are two or more solutions (inflection points) satisfying equation (2) obtained by approximation using a high-order S-shaped function, the measurement data of the metal content is approximated by a cubic function, and an inflection point closest to a solution of a second derivative equation obtained by second-order differentiation of the cubic approximation function can be estimated as the true interface position x1.

The inflection point x1 of the approximate profile of the content of the metal element obtained as described above means a position (depth in the film thickness direction) where a dominant component is switched from a component of the first etching mask film 61 to a component of the absorption layer 44. Therefore, the calculated position x1 of the inflection point can be regarded as the interface position x1 between the first etching mask film 61 and the absorption layer 44.

When the etching mask film 6 includes the second etching mask film 62, the interface position x2 between the second etching mask film 62 and the first etching mask film 61 can also be determined on the basis of the position of an inflection point where a dominant component is switched by applying the above-described curve fitting method. That is, in order to determine the interface position x2 between the second etching mask film 62 and the first etching mask film 61, a fitting curve function y_em2 (x) approximating the total content of metal elements constituting the second etching mask film 62 is calculated, and the position of an inflection point x2 obtained as a solution of a second derivative equation in which a value obtained by second-order differentiation of y_em2 (x) is zero can be regarded as the interface position x2.

The film thickness of the first etching mask film 61 described above is 6 nm to 30 nm, and can be 8 nm to 20 nm. In addition, a ratio of the film thickness of the first etching mask film 61 to the film thickness of the buffer layer 42 described above is 0.1 to 15, and can be 0.3 to 10.

The first etching mask film 61 containing Ta and O can be formed by sputtering using a Ta target in an atmosphere of an oxygen gas (O₂) and a rare gas. In addition, the first etching mask film 61 containing Si and O can be formed by sputtering using a Si target in an atmosphere of an oxygen gas (O₂) and a rare gas. At this time, by controlling a supply amount of the oxygen gas (O₂) or performing control while replacing the oxygen gas to be supplied with another gas, the first etching mask film 61 having a predetermined gradient composition of the above-described oxygen concentration ratio profile can be formed (for example, layer configuration example 1 illustrated in FIG. 2). In addition, the first etching mask film 61 having a two-layer structure or a three-layer structure can have the above-described oxygen concentration ratio profile. For example, as a three-layer structure of the layer 64, the layer 65, and the layer 66, the layer 64 and the layer 65 containing oxygen and the layer 66 substantially containing no oxygen can be formed (for example, layer configuration example 2 illustrated in FIG. 3).

In addition, by adjusting an oxygen concentration of a surface layer of the absorption layer 44 in contact with the first etching mask film 61, an oxygen concentration ratio at the interface position x1 between the first etching mask film 61 and the absorption layer 44 can be adjusted. By adjusting an oxygen concentration of a bottom of the second etching mask film 62 in contact with the first etching mask film 61, an oxygen concentration ratio at the interface position x2 between the first etching mask film 61 and the second etching mask film 62 can be adjusted.

In the reflective mask blank 100 according to the present embodiment, as described above, the second etching mask film 62 may be formed on the first etching mask film 61. In this case, a material of the second etching mask film 62 is preferably chromium (Cr) or a Cr compound. Examples of the Cr compound include a material containing chromium (Cr) and at least one element selected from nitrogen (N), oxygen (O), carbon (C), and hydrogen (H). Specifically, the second etching mask film 62 preferably contains CrN, CrO, CrC, CrON, CrOC, CrCN, or CrOCN.

The Cr content in the second etching mask film 62 is 30 at % or more, and can be 40 at % or more. The Cr content in the second etching mask film 62 is 95 at % or less, and can be 90 at % or less.

The film thickness of the second etching mask film 62 is 3 nm to 20 nm, and can be 5 nm to 15 nm.

The second etching mask film 62 can be formed by sputtering using a Cr-based target. In addition, the second etching mask film 62 contains chromium, and can be thereby etched and removed with a mixed gas of a chlorine-based gas and an oxygen gas.

### <<Resist Film>>

The reflective mask blank 100 of the present embodiment can include a resist film 11 on the etching mask film 6. That is, the reflective mask blank 100 of the present embodiment also includes a form including the resist film 11. In the reflective mask blank 100 according to the present embodiment, by selecting the absorber film 4 (the buffer layer 42 and the absorption layer 44) made of an appropriate material and/or having an appropriate film thickness and an etching gas, the resist film 11 can also be thinned.

As a material of the resist film 11, for example, a chemically amplified resist (CAR) can be used. By patterning the resist film 11 and etching the absorber film 4 (the buffer layer 42 and the absorption layer 44), the reflective mask 200 having a predetermined transfer pattern can be manufactured.

### <<Conductive Back Film>>

The conductive back film 5 for electrostatic chuck is generally formed on the second main surface (back surface) side of the substrate 1 (side opposite to the multilayer reflective film 2 forming surface). An electrical characteristic (sheet resistance) required for the conductive back film 5 for electrostatic chuck is usually 100Ω/□ (Ω/square) or less. The conductive back film 5 can be formed, for example, by a magnetron sputtering method or an ion beam sputtering method using a target of a metal such as chromium (Cr) or tantalum (Ta) or an alloy thereof.

A material containing chromium (Cr) for the conductive back film 5 is preferably a Cr compound containing Cr and at least one element selected from boron (B), nitrogen (N), oxygen (O), and carbon (C). Examples of the Cr compound include CrN, CrON, CrCN, CrCON, CrBN, CrBON, CrBCN, CrBOCN, and the like.

As a material containing tantalum (Ta) for the conductive back film 5, Ta (tantalum), an alloy containing Ta, or a Ta compound containing either Ta or an alloy containing Ta and at least one of boron (B), nitrogen (N), oxygen (O), and carbon (C) is preferably used. Examples of the Ta compound include TaB, TaN, TaO, TaON, TaCON, TaBN, TaBO, TaBON, TaBCON, TaHf, TaHfO, TaHIN, TaHfON, TaHfCON, TaSi, TaSiO, TaSiN, TaSiON, TaSiCON, and the like.

As the material containing tantalum (Ta) or chromium (Cr), the amount of nitrogen (N) present in a surface layer thereof is preferably small. Specifically, the nitrogen content of the material containing tantalum (Ta) or chromium (Cr) in the surface layer of the conductive back film 5 is preferably less than 5 at %, and more preferably, the surface layer contains substantially no nitrogen. This is because in the conductive back film 5 made of the material containing tantalum (Ta) or chromium (Cr), the lower the nitrogen content in the surface layer is, the higher wear resistance is.

The conductive back film 5 is preferably made of a material containing tantalum (Ta) and boron (B). The conductive back film 5 is made of a material containing Ta and B, and a conductive film 23 having wear resistance and chemical resistance can be thereby obtained. When the conductive back film 5 contains Ta and B, the B content is preferably 5 to 30 at %. A ratio between Ta and B (Ta:B) in a sputtering target used for forming the conductive back film 5 is preferably 95:5 to 70:30.

The film thickness of the conductive back film 5 is not particularly limited as long as a function of the conductive back film 5 for electrostatic chuck is satisfied, but is usually 10 nm to 200 nm. In addition, the conductive back film 5 also adjusts stress on the side of the second main surface of the mask blank 100, and is adjusted such that a balance with stress from various films formed on the side of the first main surface is kept and the flat reflective mask blank 100 can be obtained.

### <Reflective Mask 200 and Method for Manufacturing the Same>

An outline of a method for manufacturing the reflective mask 200 using the reflective mask blank 100 of the present embodiment will be described below.

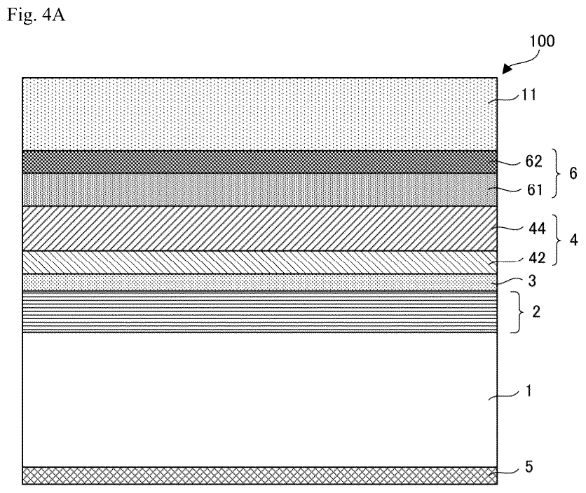

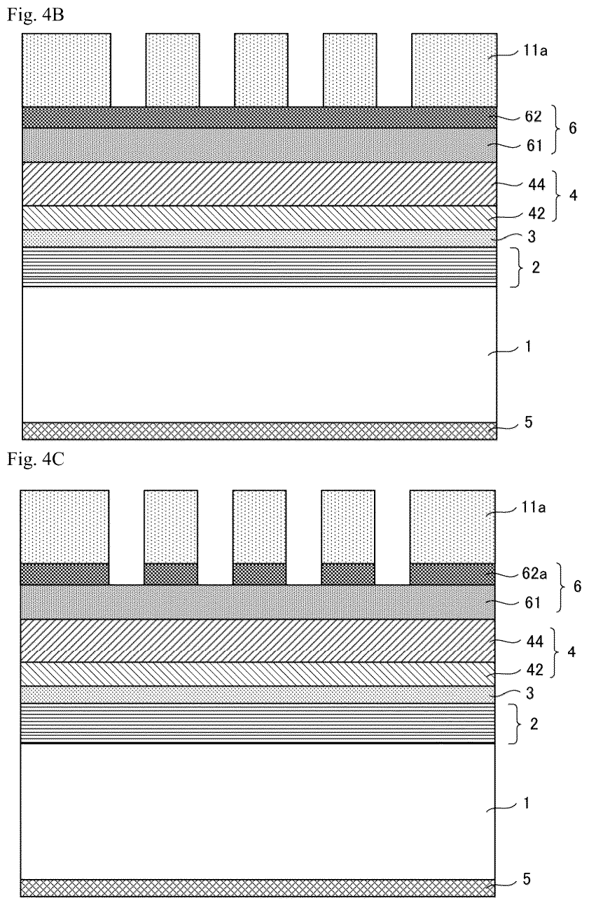

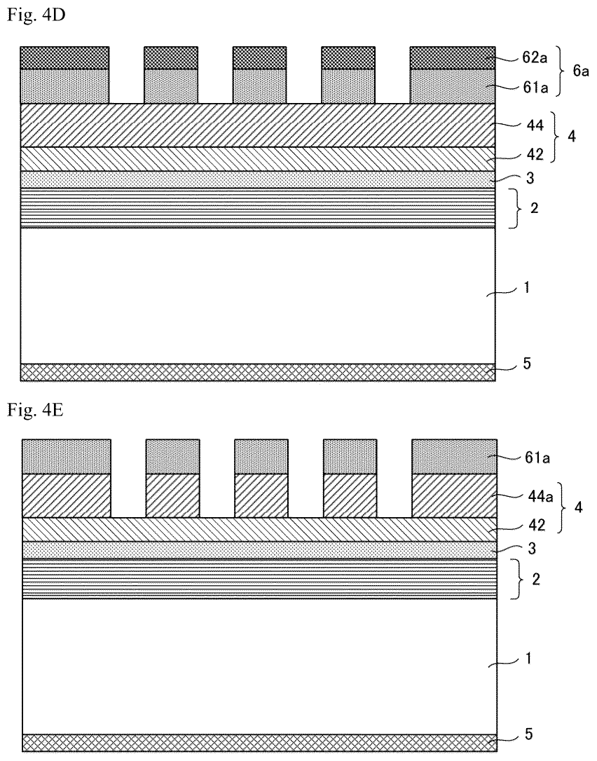

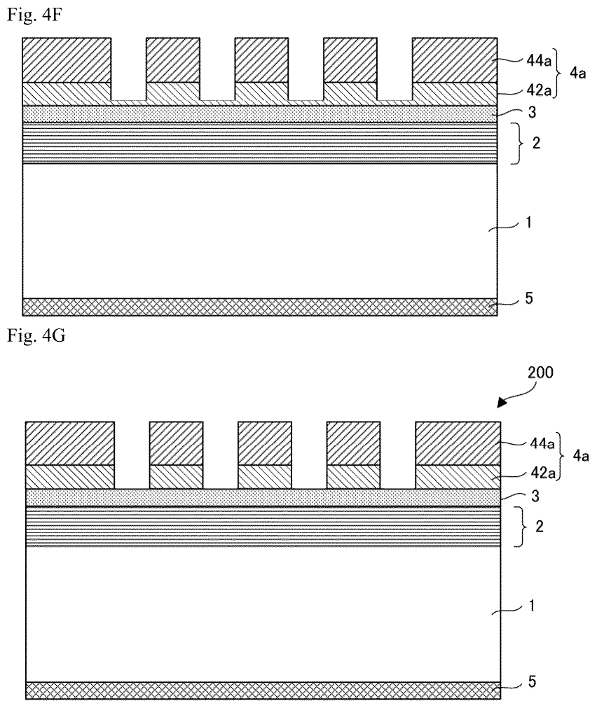

First, the reflective mask blank 100 is prepared, and the resist film 11 is formed on the etching mask film 6 formed on the absorber film 4, the top surface of the etching mask film 6 corresponding to a first main surface of the reflective mask blank 100 (FIG. 4A). A chemically amplified resist (CAR) can be used for forming the resist film 11.

A desired pattern is drawn (exposed) on the resist film 11 and further developed and rinsed, whereby a predetermined resist pattern 11a is formed (FIG. 4B).

Next, using the resist pattern 11a as a mask, the second etching mask film 62 is dry-etched using a mixed gas of a chlorine-based gas and an oxygen gas to form a mask pattern 62a (FIG. 4C).

The resist pattern 11a is peeled off by oxygen ashing. Thereafter, using the mask pattern 62a as a mask, the first etching mask film 61 is dry-etched using a fluorine-based gas to form a mask pattern 61a (FIG. 4D).

Next, using the mask pattern 61a as a mask, the absorption layer 44 is dry-etched using a mixed gas of a chlorine-based gas and an oxygen gas to form an absorption layer pattern 44a (FIG. 4E). In the dry etching step using the mixed gas of the chlorine-based gas and the oxygen gas, the mask pattern 62a of the second etching mask film 62 is removed.

Thereafter, using the absorption layer pattern 44a as a mask, the buffer layer 42 is patterned by dry etching using a fluorine-based gas. In the same step, the mask pattern 61a of the first etching mask film 61 is removed with a fluorine-based gas (FIG. 4F).

When the buffer layer 42 is not completely etched in the absorber pattern 4a after the mask pattern 61a of the first etching mask film 61 is removed, the remaining part can be completely removed using a chlorine-based gas (FIG. 4G).

Finally, by performing wet cleaning using deionized water or an acidic or alkaline aqueous solution, the reflective mask 200 of the present embodiment is manufactured. Note that by performing a mask defect inspection as necessary after the wet cleaning, a mask defect can be corrected appropriately.

The reflective mask 200 manufactured in this manner has the absorber pattern 4a in which the absorber film 4 in the reflective mask blank 100 is partnered. Since the absorber pattern 4a of the reflective mask 200 absorbs EUV light and can reflect the EUV light at an opening of the absorber pattern 4a, a predetermined fine transfer pattern can be transferred onto a transferred object by irradiating the reflective mask 200 with the EUV light using a predetermined optical system.

According to the reflective mask 200 and the method for manufacturing the same of the present embodiment, by defining the oxygen concentration ratio of the first etching mask film 61 in the reflective mask blank 100, an etching rate of the first etching mask film 61 can be adjusted according to a progress of pattern etching of the buffer layer 42. As a result, it is possible to suppress damage to the protective film 3 or the absorption layer 44 in a dry etching process of the buffer layer 42 while suppressing a CD change. Therefore, it is possible to provide the reflective mask 200 having the absorber pattern 4a in which a fine transfer pattern is formed with high accuracy.

### <Method for Manufacturing Semiconductor Device>

A method for manufacturing a semiconductor device of the present embodiment includes a step of setting the reflective mask 200 of the present embodiment in an exposure apparatus including an exposure light source that emits EUV light, and transferring a transfer pattern onto a resist film formed on a transferred substrate.

By performing EUV exposure using the reflective mask 200 of the present embodiment, a desired transfer pattern based on the absorber pattern 4a on the reflective mask 200 can be formed on a semiconductor substrate while a decrease in accuracy of a transfer dimension due to a shadowing effect is suppressed. In addition, since the absorber pattern 4a is a fine and highly accurate pattern with a small sidewall roughness, a desired pattern can be formed on the semiconductor substrate with high dimensional accuracy. Through various steps such as etching of a film to be processed, formation of an insulating film and a conductive film, introduction of a dopant, and annealing in addition to this lithography step, it is possible to manufacture a semiconductor device in which a desired electronic circuit is formed.

More specifically, the EUV exposure apparatus includes a laser plasma light source that generates EUV light, an illumination optical system, a mask stage system, a reduction projection optical system, a wafer stage system, vacuum equipment, and the like. The light source includes a debris trap function, a cut filter that cuts light having a long wavelength other than exposure light, equipment for vacuum differential pumping, and the like. The illumination optical system and the reduction projection optical system each include a reflection mirror. The reflective mask 200 for EUV exposure is electrostatically attracted by a conductive film formed on a second main surface of the reflective mask 200 and is mounted on a mask stage.

Light of the EUV light source is emitted to the reflective mask 200 through the illumination optical system at an angle tilted by 6° to 8° with respect to a vertical plane of the reflective mask 200. Reflected light from the reflective mask 200 with respect to this incident light is reflected (regularly reflected) in a direction opposite to an incident direction at the same angle as an incident angle, guided to a reflective projection system usually having a reduction ratio of ¼, and exposed on a resist on a wafer (semiconductor substrate) mounted on a wafer stage. During this time, at least a place through which EUV light passes is evacuated. In addition, when this exposure is performed, mainstream exposure is scan exposure in which scanning is performed while a mask stage and a wafer stage are synchronized at a speed corresponding to a reduction ratio of the reduction projection optical system, and exposure is performed through a slit. Then, by developing this resist film that has been subjected to exposure, a resist pattern can be formed on the semiconductor substrate. In the present invention, a mask having the highly accurate absorber pattern 4a that is a thin film having a small shadowing effect and has a small sidewall roughness is used. Therefore, the resist pattern formed on the semiconductor substrate is desired one with high dimensional accuracy. Then, by performing etching or the like using this resist pattern as a mask, a predetermined wiring pattern can be formed, for example, on the semiconductor substrate. Through such an exposure step, a step of processing a film to be processed, a step of forming an insulating film and a conductive film, a dopant introduction step, an annealing step, and other necessary steps, a semiconductor device is manufactured.

According to the method for manufacturing a semiconductor device of the present embodiment, the reflective mask 200 in which the fine and highly accurate absorber pattern 4a having a high absorptivity of EUV light can be used for manufacturing a semiconductor device while the film thickness of the absorber film 4 is reduced. Therefore, a semiconductor device having a fine and highly accurate transfer pattern can be manufactured.

### EXAMPLES

### Example 1

As illustrated in FIG. 1, a reflective mask blank 100 of Example 1 includes a conductive back film 5, a substrate 1, a multilayer reflective film 2, a protective film 3, an absorber film 4, and an etching mask film 6. The absorber film 4 includes a buffer layer 42 and an absorption layer 44.

First, the reflective mask blank 100 of Example 1 will be described. Note that, in the following description, an elemental composition of a formed thin film was measured by X-ray photoelectron spectroscopy (XPS). An oxygen concentration ratio (O/(X+O) ratio) was obtained by measuring the content of each component by energy dispersive X-ray spectroscopy (EDX) using a scanning transmission electron microscope (STEM) and performing the fitting described above.

A SiO₂—TiO₂-based glass substrate that is a low thermal expansion glass substrate which had a 6025 size (about 152 mm×152 mm×6.35 mm) and in which both main surfaces that are a first main surface and a second main surface had been polished was prepared as the substrate 1. The main surfaces were subjected to polishing including a rough polishing step, a precision polishing step, a local processing step, and a touch polishing step such that the main surfaces were flat and smooth.

The conductive back film 5 formed of a CrN film was formed on the second main surface (back surface) of the SiO₂—TiO₂-based glass substrate 1 by a magnetron sputtering (reactive sputtering) method under the following conditions. The conductive back film 5 was formed so as to have a film thickness of 20 nm in a mixed gas atmosphere of an argon (Ar) gas and a nitrogen (N₂) gas using a Cr target.

Next, the multilayer reflective film 2 was formed on the main surface (first main surface) of the substrate 1 on a side opposite to a side on which the conductive back film 5 was formed. The multilayer reflective film 2 formed on the substrate 1 was a periodic multilayer reflective film containing molybdenum (Mo) and silicon (Si) in order to make the multilayer reflective film 2 suitable for EUV light having a wavelength of 13.5 nm. The multilayer reflective film 2 was formed using a Mo target and a Si target by alternately building up a Mo layer and a Si layer on the substrate 1 by an ion beam sputtering method in a krypton (Kr) gas atmosphere. First, a Si film was formed with a film thickness of 4.2 nm, and then a Mo film was formed with a film thickness of 2.8 nm. This stack is counted as one period, the stack of a Si film and a Mo film was built up for 40 periods in a similar manner, and finally, a Si film was formed with a film thickness of 4.0 nm to form the multilayer reflective film 2.

Subsequently, the protective film 3 formed of a RuNb film was formed with a film thickness of 3.5 nm using a RuNb target (Ru:Nb=80 at %:20 at %) in an Ar gas atmosphere by a DC magnetron sputtering method.

Next, the absorber film 4 including the buffer layer 42 and the absorption layer 44 was formed on the protective film 3. Note that Table 1 presents materials and film thicknesses of the buffer layer 42, the absorption layer 44, and the etching mask film 6 of Example 1.

Specifically, first, the buffer layer 42 formed of a TaBN film was formed by a DC magnetron sputtering method. The TaBN film was formed with a film thickness of 10 nm as presented in Table 1 using a TaB mixed sintering target in a mixed gas atmosphere of an Ar gas and a N₂ gas by reactive sputtering. An element ratio of the TaBN film was 88 at % for Ta, 5 at % for B, and 7 at % for N.

Next, the absorption layer 44 formed of a CrN film was formed by a magnetron sputtering method. The CrN film was formed with a film thickness of 36 nm as presented in Table 1 using a Cr target in a mixed gas atmosphere of an Ar gas and a N₂ gas by reactive sputtering. An element ratio of the CrN film was 88 at % for Cr and 12 at % for N.

Next, a first etching mask film 61 formed of a TaBO film was formed on the absorption layer 44 by a DC magnetron sputtering method. The TaBO film was formed with a film thickness of 16 nm as presented in Table 1 using a TaB mixed sintering target in a mixed gas atmosphere of an Ar gas and an O₂ gas by reactive sputtering. At this time, by changing an O₂ gas supply amount in the mixed gas atmosphere, a composition-gradient film having different oxygen concentration ratios in the film thickness direction illustrated in Table 2 was obtained.

Next, a second etching mask film 62 formed of a CrOCN film was formed on the first etching mask film 61. The CrOCN film was formed so as to have a film thickness of 6 nm using a Cr target in an atmosphere of an Ar gas, a CO₂ gas, and a N₂ gas by a reactive sputtering method. An element ratio of the CrOCN film was 38 at % for Cr, 39 at % for O, 11 at % for C, and 12 at % for N.

As described above, the reflective mask blank 100 of Example 1 was manufactured.

Next, using the above reflective mask blank 100 of Example 1, a reflective mask 200 of Example 1 was manufactured.

A resist film 11 was formed with a thickness of 50 nm on the second etching mask film 62 of the reflective mask blank 100 (FIG. 4A). A chemically amplified resist (CAR) was used for forming the resist film 11. A desired pattern was drawn (exposed) on this resist film 11, and further developed and rinsed to form a predetermined resist pattern 11a (FIG. 4B). Next, using the resist pattern 11a as a mask, the CrOCN film (second etching mask film 62) was dry-etched using a mixed gas of a Cl₂ gas and an O₂ gas to form a mask pattern 62a (FIG. 4C). Next, the resist pattern 11a was peeled off by oxygen ashing. Thereafter, using the mask pattern 62a as a mask, the TaBO film (first etching mask film 61) was dry-etched using a mixed gas of a CF₄ gas and a He gas to form a mask pattern 61a (FIG. 4D). Using the mask pattern 61a as a mask, the CrN film (absorption layer 44) was dry-etched using a mixed gas of a Cl₂ gas and an O₂ gas to form an absorption layer pattern 44a (FIG. 4E). At this time, the CrOCN film was also peeled off at the same time.

Thereafter, using the absorption layer pattern 44a as a mask, the buffer layer 42 was patterned by dry etching using a CF₄ gas and a He gas. At this time, the mask pattern 61a formed of the TaBO film was also removed at the same time (FIG. 4F). A remaining part of the buffer layer 42 was removed with a Cl₂ gas (FIG. 4G). Finally, wet cleaning was performed with deionized water (DIW) to manufacture the reflective mask 200 of Example 1.

In the reflective mask blank 100 used for manufacturing the reflective mask 200 of Example 1, the first etching mask film 61 satisfied O/(X+O) ratio at the film thickness center x3<O/(X+O) ratio at the interface x1 and O/(X+O) ratio at the film thickness center x3<O/(X+O) ratio at the interface x2 as presented in Table 2. Therefore, excessive charging of the first etching mask film 61 could be prevented, and occurrence of fatal defects caused by electrostatic breakdown could be prevented. In addition, a CD change of the first etching mask film 61 could be suppressed, and the absorber pattern 4a having a CD of a design value ±6 nm or less could be obtained.

In addition, the reflective mask 200 manufactured in Example 1 was set in an EUV scanner, and EUV exposure was performed on a wafer on which a film to be processed and a resist film were formed on a semiconductor substrate. Then, this resist film that had been subjected to exposure was developed to form a resist pattern on the semiconductor substrate on which the film to be processed was formed. This resist pattern was transferred onto a film to be processed by etching, and through various steps such as formation of an insulating film and a conductive film, introduction of a dopant, and annealing, a semiconductor device having desired characteristics could be manufactured.

### Example 2

In Example 2, a reflective mask blank 100 and a reflective mask 200 were manufactured with a similar structure and by a similar method to those in Example 1 except for the first etching mask film 61, and a semiconductor device was manufactured by a similar method to that in Example 1.

A first etching mask film 61 formed of a layered film in which a TaBO film, a TaBN film, and a TaBO film were layered in this order was formed on an absorption layer 44 by a DC magnetron sputtering method. The TaBO film was formed using a TaB mixed sintering target in a mixed gas atmosphere of an Ar gas and an O₂ gas by reactive sputtering. The TaBN film was formed using a TaB mixed sintering target in a mixed gas atmosphere of an Ar gas and a N₂ gas by reactive sputtering. As a result, a layered film having the oxygen concentration ratio presented in Table 2 was obtained.

In the reflective mask blank 100 used for manufacturing the reflective mask 200 of Example 2, the first etching mask film 61 satisfied O/(X+O) ratio at the film thickness center x3<O/(X+O) ratio at the interface x1 and O/(X+O) ratio at the film thickness center x3<O/(X+O) ratio at the interface x2 as presented in Table 2. Therefore, excessive charging of the first etching mask film 61 could be prevented, and occurrence of fatal defects caused by electrostatic breakdown could be prevented. In addition, a CD change of the first etching mask film 61 could be suppressed, and the absorber pattern 4a having a CD of a design value ±6 nm or less could be obtained.

### Example 3

In Example 3, a reflective mask blank 100 and a reflective mask 200 were manufactured by a similar structure and method to those in Example 1 except for the first etching mask film 61, and a semiconductor device was manufactured by a similar method to that in Example 1.

A first etching mask film 61 formed of a SiO film was formed on an absorption layer 44 by an RF magnetron sputtering method. The SiO film was formed with a film thickness of 20 nm as presented in Table 1 using a Si target in a mixed gas atmosphere of an Ar gas and an O₂ gas by reactive sputtering. At this time, by changing an O₂ gas supply amount in the mixed gas atmosphere, a composition-gradient film having different oxygen concentration ratios in the film thickness direction illustrated in Table 2 was obtained.

In the reflective mask blank 100 used for manufacturing the reflective mask 200 of Example 3, the first etching mask film 61 satisfied O/(X+O) ratio at the film thickness center x3<O/(X+O) ratio at the interface x1 and O/(X+O) ratio at the film thickness center x3<O/(X+O) ratio at the interface x2 as presented in Table 2. Therefore, excessive charging of the first etching mask film 61 could be prevented, and occurrence of fatal defects caused by electrostatic breakdown could be prevented. In addition, a CD change of the first etching mask film 61 could be suppressed, and the absorber pattern 4a having a CD of a design value ±6 nm or less could be obtained.

### Comparative Example 1

In Comparative Example 1, a reflective mask blank 100 and a reflective mask 200 were manufactured by a similar structure and method to those in Example 1 except for the first etching mask film 61, and a semiconductor device was manufactured by a similar method to that in Example 1.

In the reflective mask blank 100 used for manufacturing the reflective mask 200 of Comparative Example 1, O/(X+O) ratios at the film thickness center x3, the interface x1, and the interface x2 of the first etching mask film 61 were uniformly 65%. Therefore, excessive charging exceeding an electrostatic breakdown voltage of the first etching mask film 61 occurred in the first etching mask film 61, and fatal defects that make the reflective mask defective occurred. In addition, a CD change of the first etching mask film 61 could not be suppressed, and an absorber pattern 4a having a CD exceeding a design value ±6 nm was obtained.

TABLE 1

| | | | | | | | Comparative | |
|---|---|---|---|---|---|---|---|---|
| | Example 1 | | Example 2 | | Example 3 | | Example | |
| | | Film | | Film | | Film | | Film |
| | | thickness | | thickness | | thickness | | thickness |
| Structure | Material | (nm) | Material | (nm) | Material | (nm) | Material | (nm) |
| Second | CrOCN | 6 | CrOCN | 6 | CrOCN | 6 | CrOCN | 6 |
| etching | | | | | | | | |
| mask film | | | | | | | | |
| First | TaBO | 16 | TaBO | 2 | SiO | 20 | TaBO | 16 |
| etching | (composition- | | TaBN | 12 | (composition- | | | |
| mask | gradient | | TaBO | 2 | gradient | | | |
| film | film) | | | | film) | | | |
| Absorption | CrN | 36 | CrN | 36 | CrN | 36 | CrN | 36 |
| layer | | | | | | | | |
| Buffer layer | TaBN | 10 | TaBN | 10 | TaBN | 10 | TaBN | 10 |

TABLE 2

| | Example 1 | Example 2 | Example 3 |
|---|---|---|---|
| O/(X + O) ratio (%) at | 69.0 | 74.7 | 61.9 |
| surface side x2 | | | |
| O/(X + O) ratio (%) at | 55.9 | 9.1 | 56.2 |
| film thickness center x3 | | | |
| O/(X + O) ratio (%) at | 72.3 | 81.1 | 64.1 |
| absorption layer side x1 | | | |

### REFERENCE SIGNS LIST

1 Substrate
2 Multilayer reflective film
3 Protective film
4 Absorber film
4a Absorber pattern
5 Conductive back film
6 Etching mask film
11 Resist film
42 Buffer layer
44 Absorption layer
61 First etching mask film
62 Second etching mask film
100 Reflective mask blank
200 Reflective mask

1. A reflective mask blank comprising:
a substrate;
a multilayer reflective film provided above the substrate;
an absorber film provided above the multilayer reflective film;
and an etching mask film provided above the absorber film,
wherein:
the absorber film comprises an absorption layer,
the etching mask film is provided in contact with the absorber film and comprises an element X and oxygen (O),
an oxygen concentration ratio obtained by dividing a content (at %) of oxygen (O) by a total content (at %) of the element X and oxygen (O) is defined in the etching mask film,
an oxygen concentration ratio of the etching mask film on the absorption layer side is higher than an oxygen concentration ratio at a film thickness center of the etching mask film, and
the element X comprises at least one selected from tantalum (Ta) and silicon (Si).

2. The reflective mask blank according to claim 1, wherein an oxygen concentration ratio of the etching mask film on a surface side opposite to the absorption layer is higher than the oxygen concentration ratio at the film thickness center of the etching mask film.

3. The reflective mask blank according to claim 1, wherein the etching mask film has a film thickness of 6 nm to 30 nm.

4. (canceled)

5. The reflective mask blank according to claim 1, comprising a second etching mask film on the etching mask film as a first etching mask film, wherein the second etching mask film comprises chromium (Cr).

6. (canceled)

7. The reflective mask blank according to claim 1, wherein the absorption layer comprises at least one selected from chromium (Cr) and ruthenium (Ru).

8. The reflective mask blank according to claim 1, comprising a protective film between the multilayer reflective film and the absorber film.

9. (canceled)

10. A method for manufacturing a reflective mask, the method comprising:
preparing a reflective mask blank; dry-etching an etching mask film; and
patterning an absorber film, using the etching mask film pattern as a mask,
wherein, the reflective mask blank comprises a substrate; a multilayer reflective film provided above the substrate; the absorber film provided above the multilayer reflective film; and the etching mask film provided above the absorber film,
wherein:
the absorber film comprises an absorption layer,
the etching mask film is provided in contact with the absorber film and comprises an element X and oxygen (O),
an oxygen concentration ratio obtained by dividing a content (at %) of oxygen (O) by a total content (at %) of the element X and oxygen (O) is defined in the etching mask film,
an oxygen concentration ratio of the etching mask film on the absorption layer side is higher than an oxygen concentration ratio at a film thickness center of the etching mask film, and
the element X comprises at least one selected from tantalum (Ta) and silicon (Si).

11. (canceled)

12. The reflective mask blank according to claim 8, wherein the absorber film comprises a buffer layer between the protective film and the absorption layer and the buffer layer comprises at least one selected from tantalum (Ta) and silicon (Si).

13. The reflective mask blank according to claim 8, wherein the absorber film comprises a buffer layer between the protective film and the absorption layer and a ratio of a film thickness of the etching mask film to a film thickness of the buffer layer is 0.1 to 15.

14. The reflective mask blank according to claim 1, wherein an oxide layer is provided on a surface of the absorption layer.

15. The reflective mask blank according to claim 1, wherein the oxygen concentration ratio follows a gradient from the absorption layer side to the film thickness center of the etching mask film.

16. The reflective mask blank according to claim 2, wherein the oxygen concentration ratio follows a gradient from the surface side opposite the absorption layer to the film thickness center of the etching mask film.

17. The reflective mask blank according to claim 1, wherein the oxygen concentration ratio of the etching mask film on the absorption layer side is the oxygen concentration ratio at an inflection point measured based upon a concentration of element X versus a concentration of a material of the absorption layer.

18. The method for manufacturing a reflective mask according to claim 10, wherein an oxygen concentration ratio of the etching mask film on a surface side opposite to the absorption layer is higher than the oxygen concentration ratio at the film thickness center of the etching mask film.

19. The method for manufacturing a reflective mask according to claim 10, wherein the oxygen concentration ratio follows a gradient from the absorption layer side to the film thickness center of the etching mask film.
